(19) United States
(12) Patent Application Publication
(10) Pub. No.: US 2026/0123359 A1
(43) Pub. Date: Apr. 30, 2026

(54) DEVICE AND METHOD WITH DEFECT DETECTION

(71) Applicant: SAMSUNG ELECTRONICS CO., LTD., Suwon-si (KR)

(72) Inventor: Carlos C.J ALCANTARA, Suwon-si (KR)

(73) Assignee: SAMSUNG ELECTRONICS CO., LTD., Suwon-si (KR)

(21) Appl. No.: 19/300,858

(22) Filed: Aug. 15, 2025

(30) Foreign Application Priority Data
Oct. 31, 2024 (KR) 10-2024-0152620

(51) Int. Cl. H01L 21/66; G01N 21/95

(52) U.S. Cl. CPC H10P 74/203; G01N 21/9501

(57) ABSTRACT

A device and method with defect detection are provided. The device includes a sensing assembly comprising a plurality of operation elements and a controller; and one or more processors, wherein the controller is configured to: for each of predetermined excitation patterns, activate at least one operation element using at least one control signal to propagate at least one acoustic wave toward a target object, wherein the at least one acoustic wave has at least one frequency based on the at least one operation element; and acquire a plurality of response signals corresponding to reflected waves sensed by the sensing assembly, the reflected waves being reflections of the at least one acoustic wave reflected from the target object, wherein the one or more processors are configured to: analyze the plurality of response signals using an artificial intelligence (AI) model, wherein the AI model is trained to detect defects in the target object based on inputs comprising the response signals respectively corresponding to the excitation patterns.

### CROSS-REFERENCE TO RELATED APPLICATIONS

This application claims the benefit of Korean Patent Application No. 10-2024-0152620, filed on Oct. 31, 2024, in the Korean Intellectual Property Office, the disclosure of which is incorporated herein by reference in its entirety.

### BACKGROUND

### 1. Field

The present disclosure relates to a device and method with defect detection.

### 2. Description of Related Art

In order to detect defects that occur during the manufacturing process, non-destructive defect detection methods are typically employed. In particular, non-destructive detecting utilizing sound resonance is widely used.

### SUMMARY

This Summary is provided to introduce a selection of concepts in a simplified form that are further described below in the Detailed Description. This Summary is not intended to identify key features or essential features of the claimed subject matter, nor is it intended to be used as an aid in determining the scope of the claimed subject matter.

In one general aspect, an electronic device for defect detection, comprising: a sensing assembly comprising a plurality of operation elements and a controller; and one or more processors, wherein the controller is configured to: for each of predetermined excitation patterns, activate at least one operation element using at least one control signal to propagate at least one acoustic wave toward a target object, wherein the at least one acoustic wave has at least one frequency based on the at least one operation element; and acquire a plurality of response signals corresponding to reflected waves sensed by the sensing assembly, the reflected waves being reflections of the at least one acoustic wave reflected from the target object, wherein the one or more processors are configured to: analyze the plurality of response signals using an artificial intelligence (AI) model, wherein the AI model is trained to detect defects in the target object based on inputs comprising the response signals respectively corresponding to the excitation patterns.

In one general aspect, a defect detection method for an electronic device comprising one or more processors and a sensing assembly with a plurality of operation elements and a controller, the method comprising: activating, via the controller, for each of predetermined excitation patterns, at least one operation element using at least one control signal to propagate at least one acoustic wave toward a target object; wherein the at least one acoustic wave has at least one frequency based on the at least one operation element; acquiring, via the controller, a plurality of response signals corresponding to reflected waves sensed by the sensing assembly, the reflected waves being reflections of the at least one acoustic wave reflected from the target object; and determining, via the one or more processors, a defect status of the target object by analyzing an artificial intelligence (AI) model trained to correlate the response signals with defects

In one general aspect, a non-transitory computer-readable recording medium storing instructions that, when executed by a processor, causes the processor to perform the method described herein.

Other features and aspects will be apparent from the following detailed description, the drawings, and the claims.

### BRIEF DESCRIPTION OF THE DRAWINGS

These and/or other aspects, features, and advantages of the invention will become apparent and more readily appreciated from the following description of example embodiments, taken in conjunction with the accompanying drawings of which:

FIG. 1 illustrates an electronic device according to one or more embodiments;

FIG. 2 illustrates a method of manufacturing an operation element according to one or more embodiments;

FIG. 3 illustrates a plurality of operation elements and a controller that are connected through a through-silicon-via (TSV) interposer according to one or more embodiments;

FIG. 4 illustrates an excitation mode of an operation element according to one or more embodiments;

FIG. 5 illustrates a sensing mode of an operation element according to one or more embodiments;

FIG. 6 illustrates a method of determining whether a target object is defective using an artificial intelligence model according to one or more embodiments; and

FIG. 7 is a flowchart illustrating a defect detection method of an electronic device according to one or more embodiments.

### DETAILED DESCRIPTION

The following detailed description is provided to assist the reader in gaining a comprehensive understanding of the methods, apparatuses, and/or systems described herein. However, various changes, modifications, and equivalents of the methods, apparatuses, and/or systems described herein will be apparent after an understanding of the disclosure of this application. For example, the sequences of operations described herein are merely examples, and are not limited to those set forth herein, but may be changed as will be apparent after an understanding of the disclosure of this application, with the exception of operations necessarily occurring in a certain order. Also, descriptions of features that are known after an understanding of the disclosure of this application may be omitted for increased clarity and conciseness.

The features described herein may be embodied in different forms and are not to be construed as being limited to the examples described herein. Rather, the examples described herein have been provided merely to illustrate some of the many possible ways of implementing the methods, apparatuses, and/or systems described herein that will be apparent after an understanding of the disclosure of this application.

The terminology used herein is for describing various examples only and is not to be used to limit the disclosure. The articles “a,” “an,” and “the” are intended to include the plural forms as well, unless the context clearly indicates otherwise. As used herein, the term “and/or” includes any one and any combination of any two or more of the associated listed items. As non-limiting examples, terms “comprise” or “comprises,” “include” or “includes,” and “have” or “has” specify the presence of stated features, numbers, operations, members, elements, and/or combinations thereof, but do not preclude the presence or addition of one or more other features, numbers, operations, members, elements, and/or combinations thereof.

Throughout the specification, when a component or element is described as being “connected to,” “coupled to,” or “joined to” another component or element, it may be directly “connected to,” “coupled to,” or “joined to” the other component or element, or there may reasonably be one or more other components or elements intervening therebetween. When a component or element is described as being “directly connected to,” “directly coupled to,” or “directly joined to” another component or element, there can be no other elements intervening therebetween. Likewise, expressions, for example, “between” and “immediately between” and “adjacent to” and “immediately adjacent to” may also be construed as described in the foregoing.

Although terms such as “first,” “second,” and “third”, or A, B, (a), (b), and the like may be used herein to describe various members, components, regions, layers, or sections, these members, components, regions, layers, or sections are not to be limited by these terms. Each of these terminologies is not used to define an essence, order, or sequence of corresponding members, components, regions, layers, or sections, for example, but used merely to distinguish the corresponding members, components, regions, layers, or sections from other members, components, regions, layers, or sections. Thus, a first member, component, region, layer, or section referred to in the examples described herein may also be referred to as a second member, component, region, layer, or section without departing from the teachings of the examples.

Unless otherwise defined, all terms, including technical and scientific terms, used herein have the same meaning as commonly understood by one of ordinary skill in the art to which this disclosure pertains and based on an understanding of the disclosure of the present application. Terms, such as those defined in commonly used dictionaries, are to be interpreted as having a meaning that is consistent with their meaning in the context of the relevant art and the disclosure of the present application and are not to be interpreted in an idealized or overly formal sense unless expressly so defined herein. The use of the term “may” herein with respect to an example or embodiment, e.g., as to what an example or embodiment may include or implement, means that at least one example or embodiment exists where such a feature is included or implemented, while all examples are not limited thereto.

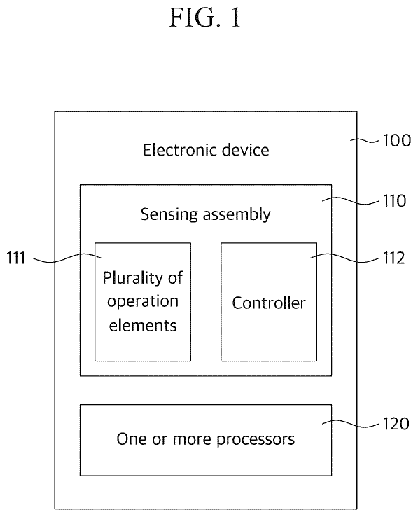

FIG. 1 illustrates an electronic device according to one or more embodiments.

Referring to FIG. 1, an electronic device 100 may include a sensing assembly 110 and one or more processors 120. The sensing assembly 110 may be a sensing assembly configured to incorporate a plurality of operation elements 111 and a controller 112. Both the controller 112 and the one or more processors 120 may be implemented as one or more processors respectively including processing circuitry. With respect to the electronic device 100 which is illustrated in FIG. 1, only elements associated with the present example embodiment are illustrated. Thus, those skilled in the art may understand that other elements in general use in addition to the elements illustrated in FIG. 1 may be further included.

In one embodiment, a target object may be a wafer. In other words, the electronic device 100 may be configured to detect defects in a wafer within a semiconductor manufacturing line, although this is provided only by way of example. In other embodiments, the target object is not limited to the wafer, and the electronic device 100 may be used in non-destructive defect detection methods for a variety of objects. For example, a defect detection method may be applied in fields such as medical imaging and materials science.

In one embodiment, the sensing assembly 110 may operate in two operation modes: an excitation mode, in which an acoustic wave is propagated toward the target object, and a sensing mode, in which a reflected wave reflected from the target object is received to acquire a response signal corresponding to the reflected wave. Using unique and inherent characteristics of the acoustic wave, which does not damage the target object, the sensing assembly 110 may operate in both modes without contacting or damaging the target object. Thus, the sensing assembly 110 may rapidly scan a surface of the target object in a non-destructive manner.

In one embodiment, an operation element may be selectively activated or deactivated in accordance with an excitation pattern. Such an operation element may serve to both propagate the acoustic wave toward the target object and receive the reflected wave reflected from the target object. As a non-limiting example, the operation element may be implemented as a micro electro mechanical systems (MEMS).

In one embodiment, the plurality of operation elements 111 within the sensing assembly 110 may be arranged in an array. When the operation element is implemented as a MEMS, since the operation element may be miniaturized up to a nanometer scale, the plurality of operation elements 111 may be densely packed within the array. Consequently, the electronic device 100 may precisely scan the surface of the target object by minutely adjusting the acoustic wave propagated through the plurality of operation elements 111.

In one embodiment, the controller 112 may be configured to control the operation elements 111. As a non-limiting example, the controller 112 may be implemented using complementary metal-oxide-semiconductor (CMOS) technology.

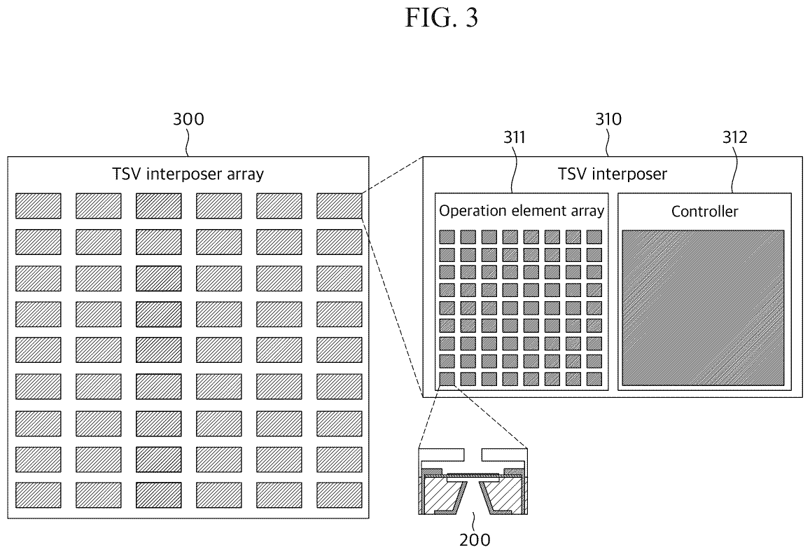

In one embodiment, the operation elements 111 controlled by the controller 112 may operate in either the excitation mode or the sensing mode. When the controller 112 applies a bias voltage to the operation element 111, the operation element 111 operates in the excitation mode; conversely, when no bias voltage is applied to the operation element 111, the operation element 111 operates in the sensing mode. The controller 112 may be connected to the plurality of operation elements 111 via a plurality of channels, transmitting control signals to the operation elements 111 and receiving the corresponding response signals from the operation elements 111. As a non-limiting example, the plurality of channels may individually respectively correspond to the operation elements 111. Embodiments wherein the plurality of operation elements 111 and the controller 112 are interconnected via a through-silicon-via (TSV) interposer will be described in detail with reference to FIG. 3.

In one embodiment, the excitation pattern may involve activating one or more operation elements among the plurality of operation elements 111 while the remaining operation elements are inactivated. The one or more operation elements that are activated may vary depending on each of the excitation patterns. In this manner, an acoustic wave corresponding to a specific frequency may be propagated in each activated operation element in a predetermined excitation pattern, while the inactivated operation elements do not propagate the acoustic wave.

In one embodiment, operation elements activated in each of a plurality of predetermined excitation patterns may not be identical. Since each of the plurality of operation elements 111 may be positioned proximate to a corresponding area of the target object, the electronic device 100 can effectively scan the entire surface (including all required areas) of the target object by ensuring that each operation element is activated at least once over the course of the plurality of excitation patterns. In other words, different areas of the target object may be scanned by different excitation patterns, with each excitation pattern being geometrically suited to its target area.

In one embodiment, the one or more processors 120 may determine whether the target object is defective by using a pre-trained artificial intelligence (AI) model. The AI model receives, as an input, a plurality of response signals corresponding to the plurality of excitation patterns. Here, the AI model may be trained, using first learning data including response signals from first objects of which defects have not been detected and second learning data including response signals from second objects of which defects have been detected, thereby enabling it to distinguish the first objects (i.e., non-defective objects) and the second objects (i.e., defective objects). For example, the AI model may utilize a recurrent neural network (RNN)-based dynamic system reconfiguration to classify the target object as defective or normal. As used herein, an object without a detected defect may also be referred to as a first object, and an object with a detected defect may also be referred to as a second object.

Although not illustrated in FIG. 1, the electronic device 100 may further include an interface device. The interface device may display information regarding whether the target object is defective, as well as a specific location on the target object where a defect or particle (e.g., dust) is detected. Also, the defect of the target object may take various forms, such as a crack or a groove, among other possibilities.

In one embodiment, the electronic device 100 may acquire the plurality of response signals corresponding to each of excitation patterns. In other words, as only at least a portion of the plurality of operation elements 111 is activated according to the excitation patterns, the electronic device 100 may rapidly scan a surface of the target object in various excitation patterns. The electronic device 100 may determine whether the target object is defective by using AI model that receives, as an input, the plurality of response signals corresponding to each of the excitation patterns. In this manner, whether the target object is defective may be accurately identified by comparing the plurality of response signals corresponding to each of the excitation patterns of the target object and a plurality of response signals in a non-defective object, which corresponds to each of the plurality of excitation patterns.

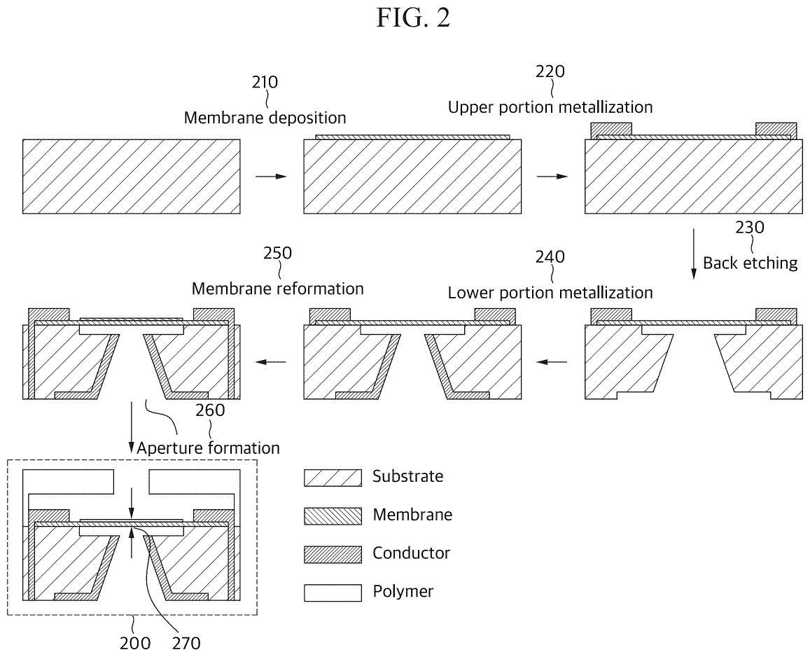

FIG. 2 illustrates a method of manufacturing an operation element according to one or more embodiments.

In one embodiment, an operation element 200 may be implemented as a MEMS. The operation element 200 may be manufactured through a series of processes, including membrane deposition 210, upper portion metallization 220, back etching 230, lower portion metallization 240, membrane reformation 250, and aperture formation 260. While the membrane deposition 210, the upper portion metallization 220, the back etching 230, and the lower portion metallization 240 may be standard processes in general MEMS fabrication, the membrane reformation 250 and the aperture formation 260 may be additional processes specifically incorporated for fabricating the MEMS used in the defect detection method described herein. As a non-limiting example, the membrane reformation 250 and the aperture formation 260 may be performed using a stack manufacturing technology, such as depositing a polymer via two-photon lithography.

In one embodiment, the membranes deposited during the membrane deposition 210 may initially exhibit substantially equal thickness. To produce films with varying thicknesses in the operation element 200, the membrane reformation 250 may be employed to adjust thicknesses of films of the operation element 200 so that the film thicknesses are different. During the process of the membrane reformation 250, the films of the operation element 200 may acquire different thicknesses. as indicated by reference numeral 270. As a non-limiting example, a film thickness may be defined as the sum of a thickness of a membrane deposited by the membrane deposition 210 and a thickness of a polymer added during the membrane reformation 250.

In addition, the aperture formation 260 may be performed to form an aperture in the operation element 200. This aperture enables an acoustic wave to be propagated to a target object through the operation element 200. Accordingly, the acoustic wave propagated through the operation element 200 may be propagated to the target object through the aperture, and any reflected wave reflected from the target object may be received to the operation element 200 through the same aperture.

In one embodiment, a frequency corresponding to the operation element 200 may be determined as a resonant frequency based on the film thickness of the operation element 200. For example, the resonant frequency may decrease as the film thickness increases; however, this is provided only by way of example.

In one embodiment, the acoustic wave corresponding to the operation element 200 may be either frequency-modulated or amplitude-modulated based on the resonant frequency based on the film thickness. Although both amplitude modulation and frequency modulation techniques may be applied, a range within which modulation is permitted may be limited. Accordingly, to allow the films included in the operation element 200 to have varying thicknesses from each other, the membrane reformation 250 may be incorporated into the manufacturing processes of the operation element 200.

FIG. 3 illustrates a plurality of operation elements and a controller that are connected through a through-silicon-via (TSV) interposer according to one or more embodiments.

In one embodiment, the electronic element 100 may include the controller 112 and the plurality of operation elements 111 which are connected through an intermediate substrate. As a non-limiting example, the intermediate substrate may be the TSV interposer, through which the controller 112 and the plurality of operation elements 111 may be packaged. When the controller 112 and the operation element 111 are interconnected via the TSV interposer, a signal delay between the controller 112 and the operation elements 111 may be minimized, and power consumption associated with the operation of the sensing assembly 110 also may be minimized.

In one embodiment, when an acoustic wave is propagated on a first surface of the sensing assembly 110 and a reflected wave is reflected on a second surface of a target object, an area of the first surface of the sensing assembly 110 may be larger than an area of the second surface of the target object. The first surface refers to the surface of the sensing assembly 110 where an acoustic wave propagates, while the second surface refers to the surface of the target object where the reflected wave is generated. This configuration may minimize nonlinear effects occurring at an edge portion of the sensing assembly 110.

In one embodiment, the sensing assembly 110 may correspond to the TSV interposer. Referring to FIG. 3, a TSV interposer 310 may include an operation element array 311 and a controller 312. The operation element array 311 may incorporate the operation element 200 and a plurality of operation elements that are manufactured by the manufacturing method of FIG. 2. The controller 312 may be connected to the plurality of operation elements 111 through a plurality of channels. However, depending on the performance of the controller 312 or the number of the channels, the number of the plurality of operation elements 111 that are connectable to one controller 312 may be limited.

Furthermore, to minimize the nonlinear effect, the area of the first surface of the sensing assembly 110 may be designed to be larger than that of the second surface of the target object. In this regard, the sensing assembly 110 may comprise a TSV interposer array 300 including a plurality of TSV interposers 310. In such an embodiment, the electronic device 100 may include a plurality of controllers 312 corresponding to the plurality of TSV interposers 310. For example, as shown in FIG. 3, the TSV interposer array 300 may include fifty-four TSV interposers 310, although this is provided only by way of example. Since the TSV interposers 310 may be substantially identical to each other, the number of the TSV interposers 310 within the TSV interposer array 300 may be variably adjusted in accordance with a surface size of the target object. In a non-limiting example, as the first surface of the sensing assembly 110 may be proportional to a size of the TSV interposer array 300, a defect detection method may be applied to target objects of varying sizes.

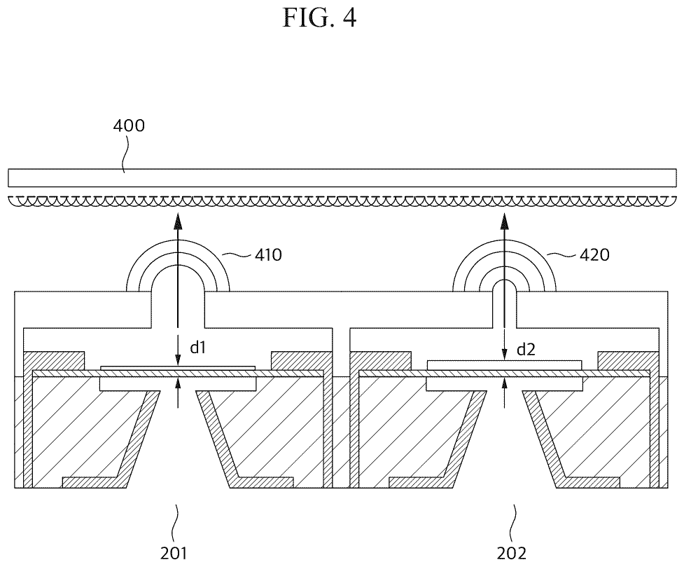

FIG. 4 illustrates an excitation mode of an operation element according to one or more embodiments.

In one embodiment, the controller 112 may transmit at least one control signal to at least one operation element, thereby causing at least one acoustic wave, which has at least one frequency based on the at least one operation element corresponding to an excitation pattern, to propagate toward a target object 400. Referring to FIG. 4, two operation elements illustrated in this example are a first operation element 201 and a second operation element 202, while the corresponding acoustic waves are a first acoustic wave 410 and a second acoustic wave 420. In this illustration, only a subset of the plurality of operation elements 111 is shown.

In one embodiment, the control signal may include information on a bias voltage to be applied to the operation element. This information may include information on a voltage amplitude and information on a voltage frequency. When the bias voltage having the voltage amplitude and the voltage frequency is applied to the operation element, mechanical deformation occurs in a film of the operation element, causing the film to vibrate. As vibration of the film is transmitted through the surrounding air, an acoustic wave having a predetermined frequency is generated. Thus, the predetermined frequency of the acoustic wave may be based on the bias voltage applied to the operation element and the film thickness of the operation element.

For example, a first bias voltage corresponding to a first control signal may be applied to the first operation element 201, which has a film thickness d1. Accordingly, the first acoustic wave 410 may exhibit a frequency corresponding to the first bias voltage and d1. Similarly, a second bias voltage corresponding to a second control signal may be applied to the second operation element 202, which has a film thickness d2. Consequently, the second acoustic wave 420 may exhibit a frequency corresponding to the second bias voltage and d2.

The generated acoustic waves 410 and 420 may interact with each other as they propagate, causing constructive interference or destructive interference before reaching a surface of the target object 400. Referring to FIG. 4, both the first acoustic wave 410 and the second acoustic wave 420 may reach the surface of the target object 400, where their interference patterns contribute to the overall acoustic signal received.

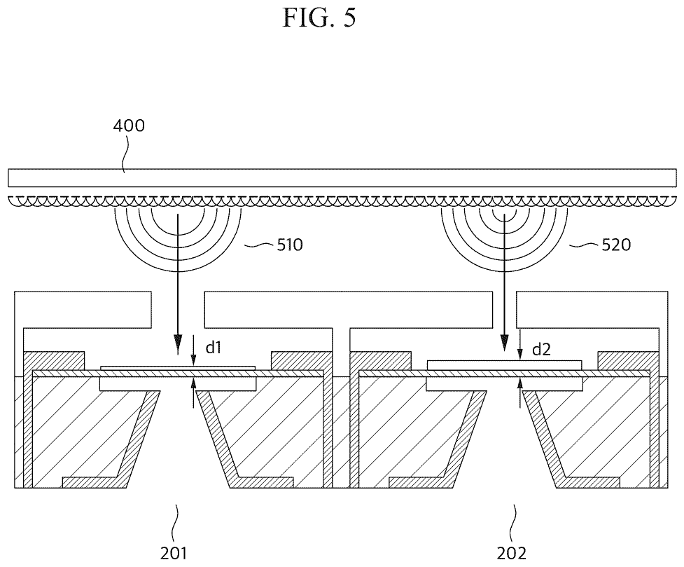

FIG. 5 illustrates a sensing mode of an operation element according to one or more embodiments.

In one embodiment, after the sensing assembly 110 operates in an excitation mode, the sensing assembly 110 may transition from the excitation mode to the sensing mode. In the sensing mode, the controller 112 may be configured to withhold the application of a bias voltage to the plurality of operation elements 111.

At least one acoustic wave that reaches a surface of a target object may be reflected. A reflected wave that occurs in response to the at least one acoustic wave being reflected may be received by the plurality of operation elements 111. That is, the reflected wave may be received even by an operation element that does not emit the acoustic wave. Mechanical deformation may occur in a film of an operation element in response to the reflected wave being received, causing a voltage value of the operation element to change in proportion to a degree of deformation (e.g., bending) of the film of the operation element. Consequently, the sensing assembly 110 may acquire a plurality of response signals in the form of voltage signals corresponding to the plurality of operation elements 111.

In one embodiment, FIG. 5 illustrates two reflected waves 510 and 520 from the surface of a non-defective target object 500. In such cases, the scattering patterns in which the reflected waves 510 and 520 are scattered after the corresponding acoustic waves are reflected on a surface of the non-defective object 500 may be similar. Therefore, the plurality of voltage signals acquired by the sensing assembly 110 may have values similar, within a set range, to those of a plurality of voltage signals acquired through another non-defective object.

In contrast, when a target object is defective, the scattering patterns of the reflected waves may differ after the corresponding acoustic waves are reflected on the surface of the defective target object. Specifically, the reflected wave which is received by an operation element adjacent to a defective area may differ from the reflected wave which is received in a defect-free scenario. As a result, the response signal from the operation element adjacent to the defect may fall outside the set range established by signals from a non-defective object.

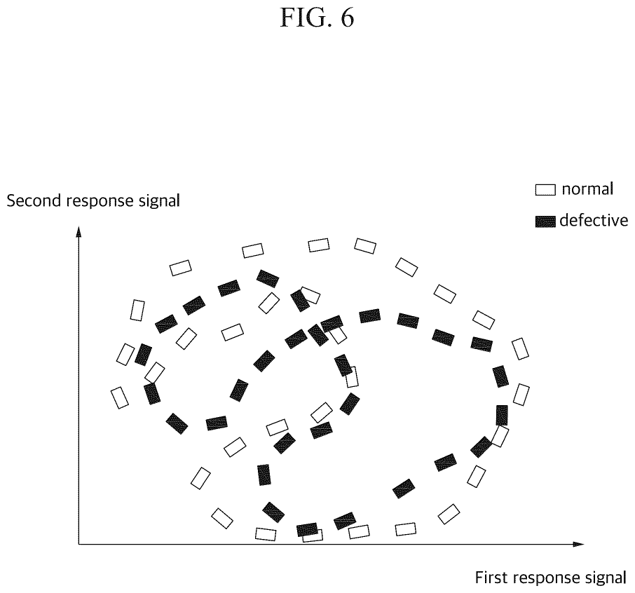

In one embodiment, the one or more processors 120 may determine whether the target object is defective by comparing the plurality of response signals obtained from the target object, which correspond to a plurality of excitation patterns, with a plurality of response signals from a non-defective object. More specifically, FIG. 6 illustrates a method for determining defectiveness using an artificial intelligence model that receives the plurality of response signals from the target object as input.

FIG. 6 illustrates a method of determining whether a target object is defective using an artificial intelligence (AI) model according to one or more embodiments.

In one embodiment, the AI model may be configured to classify a target object as either being defective or normal based on a plurality of response signals. Each response signal corresponds to one of a plurality of excitation patterns. As a non-limiting example, the AI model may perform this classification via an RNN-based dynamic system reconfiguration.

In one embodiment, the AI model may be trained using two sets of learning data. The first learning data may include learning data from a plurality of non-defective objects, and the second set may include learning data from a plurality of defective objects. Here, the first learning data may include matrix data representing first response signals each corresponding to a pair formed by one pattern among the plurality of excitation patterns and one object among the first objects, and the second learning data may include matrix data representing second response signals each corresponding to a pair formed by one pattern among the plurality of excitation patterns and one object among the second objects. In addition, the learning data may include label data that identifies whether each scanned object is defective, with the response signals obtained through a defect detection method.

In one embodiment, the number of excitation patterns may be N, and the number of operation elements may each be M. The learning data which indicates a plurality of response signals in an object corresponding to the plurality of excitation patterns may be matrix data. In this regard, a row of the matrix data may correspond to the plurality of excitation patterns, and a column of the matrix data may correspond to an operation element. For example, v_{i, j} that is an element corresponding to an i-th row and a j-th column of the matrix data may represent a response signal in a j-th operation element in a case in which the sensing assembly 110 operates in an i-th excitation pattern.

As described above, since the scattering patterns of acoustic waves reflected from a non-defective target object may be substantially identical, the corresponding pieces of matrix data which individually correspond to the first objects (i.e., non-defective objects) may exhibit similar values. In other words, elements at an equal position that are included in the pieces of matrix data have similar values within a set range. In contrast, for defective target objects, the scattering patterns may be different from each other, pieces of matrix data which individually correspond to the second objects (i.e., defective objects) may be partially different from the pieces of matrix data which individually correspond to the first objects (i.e., non-defective objects). Thus, the values of some elements in the matrix data of a defective object fall outside the set range observed in non-defective objects.

In one embodiment, the AI model may accurately classify the target object as being defective or normal by comparing the plurality of response signals in the target object—each corresponding to one of the plurality of excitation patterns—with the response pattern derived from non-defective (first) object.

Referring to FIG. 6, a dot plot is used in which the x-axis represents a first response signal in the object corresponding to one of the plurality of excitation patterns and the y-axis represents a second response signal in the object corresponding to one of the plurality of excitation patterns. In this example, the first response signal is obtained from a reflected wave sensed by a first operation element, and the second response signal is obtained from a reflected wave sensed by a second operation element.

In one embodiment, the number of the plurality of excitation patterns may be 31. In this scenario, points representing response signals are grouped into two sets: a first set including points representing first response signals corresponding to non-defective (normal) objects and a second set including points representing second response signals corresponding to defective objects. When points representing the response signals corresponding to the target object are close to the first set, the target object may be classified as normal. In contrast, when the points representing the response signals corresponding to the target object are distant from the first set and close to the second set or distributed in another form, the target object may be classified as defective.

In addition, although FIG. 6 illustrates only the first and second response signals—corresponding to the reflected wave sensed by the first and second operation elements, respectively—this illustration is merely an example. When the system includes N operation elements, a response signal corresponding to a reflected wave sensed by another operation element may be positioned in a N-dimensional space together with the first response signal corresponding to the reflected wave sensed by the first operation element and the second response signal corresponding to the reflected wave sensed by the second operation element. The one or more processors 120 may then accurately classify the target object as being defective or normal based on the relative positions in the N-dimensional space of the plurality of response signals in the target object compared to those from the first object (i.e., non-defective object).

In one embodiment, a position of a defect in the target object may be identified by analyzing the positions, in the N-dimensional space, of the plurality of response signals in the target object, which correspond to each of the plurality of excitation patterns and the plurality of response signals in the first object (i.e., the non-defective object), which correspond to each of the plurality of excitation patterns. For example, when differences between response signals, of operations elements positioned close to the first operation element, in the target object and response signals, of the operation elements, in the first object are greater than or equal to a set value (e.g., a predetermined threshold), a defect is identified as occurring in the vicinity of the first operation element.

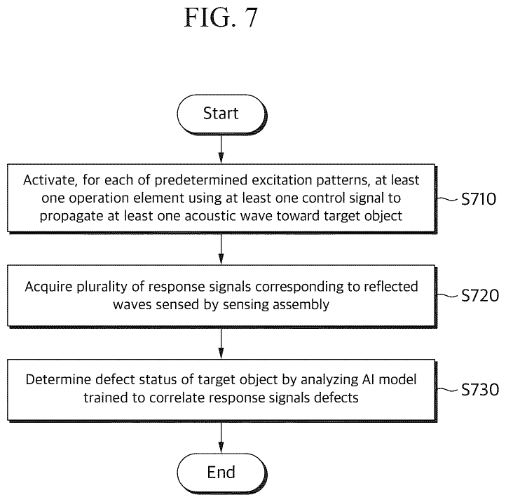

FIG. 7 is a flowchart illustrating a defect detection method for an electronic device according to one or more embodiments.

Referring to FIG. 7, certain operations of the defect detection method for the electronic device 100 may be modified, substituted, or performed in a different order, provided that such variations fall within the understanding of those skilled in the art.

In operation S710, the electronic device 100 may activate, via the controller 112, for each of predetermined excitation patterns, at least one operation element using at least one control signal to propagate at least one acoustic wave toward a target object. The at least one acoustic wave has at least one frequency based on the at least one operation element. This causes at least one acoustic wave, having a predetermined frequency and associated with an excitation pattern, to propagate from the at least one operation element toward a target object.

In one embodiment, the target object may be a wafer, and the electronic device 100 may function as a defect detection device in a semiconductor manufacturing line. The control signal may include information on a bias voltage applied to the operation element. When the bias voltage, which has its associated voltage amplitude and voltage frequency corresponding to the control signal, is applied to the operation element, mechanical deformation may occur in a film of the operation element, causing the film to vibrate. As vibration of the film is transferred through surrounding air, an acoustic wave with a predetermined frequency is generated.

In operation S720, the electronic device 100 may acquire, via the controller 112, a plurality of response signals corresponding to reflected waves sensed by the sensing assembly 110, the reflected waves being reflections of the at least one acoustic wave reflected from the target object. In one embodiment, a voltage value of the operation element may change in proportion to a degree to which the film of the operation element, upon receiving a reflected wave, deforms. Accordingly, the sensing assembly 110 may acquire, as the plurality of response signals, a plurality of voltage signals corresponding to the plurality of operation elements 111.

In operation S730, the one or more processors 100 may determine, via the one or more processors 120, a defect status of the target object by analyzing an AI model trained to correlate the response signals with defects. The electronic device 100 may perform the defect detection method after each step of a multi-step manufacturing process for the target object. The electronic device 100 may generate an alert identifying a specific manufacturing step when defects reaching or exceeding a predetermined threshold are detected in the target object after said step.

In one embodiment, the one or more processors 120 may accurately classify the target object as defective or normal based on the positions, in a multidimensional space, of the plurality of response signals in the target object. These positions are compared with the positions of the plurality of response signals from a non-defective (first) object corresponding to each excitation pattern.

In one embodiment, the defect detection method for the target object may be performed following the completion of each of a plurality of detailed processes in the manufacturing process. The electronic device 100 may be positioned in a later stage of these processes and integrated into a manufacturing process cluster for the target object, so that the defect detection method for the target object may be performed after each of a plurality of detailed processes is completed.

When the target object is identified as having a defect in a predetermined proportion (e.g., 5% or more), the electronic device 100 may transmit information to a server indicating that the defect of the target object occurs during a corresponding detailed process. In other words, when the target object is identified by the electronic device 100 as having the defect in the set proportion, the electronic device 100 may communicate that the defect is attributable to the corresponding process. This early detection facilitates prompt corrective action—such as replacing a device used in the process—thus reducing the overall defect rate, increasing the manufacturing yield, improving product quality, and accelerating the development and release cycles for the target object.

The electronic device 100 according to the above-described examples and embodiments may include a processor, a memory that stores and executes program data, a permanent storage such as a disk drive, a communication port for communicating with an external device, and a user interface device such as a touch panel, a key, and a button. Methods implemented by software modules or algorithms may be stored in a computer-readable recording medium as computer-readable code or program instructions executable in the processor. Here, the computer-readable recording medium may include a magnetic storage medium (e.g., a read-only memory (ROM), a random-access memory (RAM), a floppy disk, a hard disk, or the like), an optical reading medium (e.g., a CD-ROM or a digital versatile disc (DVD)), or the like. The computer-readable recording medium may be dispersed to computer systems connected by a network so that computer-readable codes may be stored and executed in a dispersed manner. The medium may be read by a computer, stored in the memory, and executed by the processor.

The examples and embodiments may be represented by functional blocks and various processing steps. These functional blocks may be implemented by various numbers of hardware and/or software configurations (e.g., as code/instructions) that execute specific functions. For example, the present example embodiments may adopt integrated circuit configurations such as a memory, a processor, a logic circuit, and a look-up table that may execute various functions by control of one or more microprocessors or other control devices. Similarly to that elements may be executed by software programming or software elements, the present example embodiments may be implemented by programming or scripting languages such as C, C++, Java, and assembler language, including various algorithms implemented by combinations of data structures, processes, routines, or of other programming configurations. Functional aspects may be implemented by algorithms executed by one or more processors. In addition, the present example embodiments may adopt the related art for electronic environment setting, signal processing, and/or data processing, for example.

The electronic devices, the operation elements, the controllers, the one or more processors, the sensing assemblies, and hardware, the storage devices, and other apparatuses, devices, models, and components described herein with respect to FIGS. 1-7 are implemented by or representative of hardware components. Examples of hardware components that may be used to perform the operations described in this application where appropriate include controllers, sensors, generators, drivers, memories, comparators, arithmetic logic units, adders, subtractors, multipliers, dividers, integrators, and any other electronic components configured to perform the operations described in this application. In other examples, one or more of the hardware components that perform the operations described in this application are implemented by computing hardware, for example, by one or more processors or computers. A processor or computer may be implemented by one or more processing elements, such as an array of logic gates, a controller and an arithmetic logic unit, a digital signal processor, a microcomputer, a programmable logic controller, a field-programmable gate array, a programmable logic array, a microprocessor, or any other device or combination of devices that is configured to respond to and execute instructions in a defined manner to achieve a desired result. In one example, a processor or computer includes, or is connected to, one or more memories storing instructions or software that are executed by the processor or computer. Hardware components implemented by a processor or computer may execute instructions or software, such as an operating system (OS) and one or more software applications that run on the OS, to perform the operations described in this application. The hardware components may also access, manipulate, process, create, and store data in response to execution of the instructions or software. For simplicity, the singular term “processor” or “computer” may be used in the description of the examples described in this application, but in other examples multiple processors or computers may be used, or a processor or computer may include multiple processing elements, or multiple types of processing elements, or both. For example, a single hardware component or two or more hardware components may be implemented by a single processor, or two or more processors, or a processor and a controller. One or more hardware components may be implemented by one or more processors, or a processor and a controller, and one or more other hardware components may be implemented by one or more other processors, or another processor and another controller. One or more processors, or a processor and a controller, may implement a single hardware component, or two or more hardware components. A hardware component may have any one or more of different processing configurations, examples of which include a single processor, independent processors, parallel processors, single-instruction single-data (SISD) multiprocessing, single-instruction multiple-data (SIMD) multiprocessing, multiple-instruction single-data (MISD) multiprocessing, and multiple-instruction multiple-data (MIMD) multiprocessing.

The methods illustrated in FIGS. 1-7 that perform the operations described in this application are performed by computing hardware, for example, by one or more processors or computers, implemented as described above implementing instructions or software to perform the operations described in this application that are performed by the methods. For example, a single operation or two or more operations may be performed by a single processor, or two or more processors, or a processor and a controller. One or more operations may be performed by one or more processors, or a processor and a controller, and one or more other operations may be performed by one or more other processors, or another processor and another controller. One or more processors, or a processor and a controller, may perform a single operation, or two or more operations.

Instructions or software to control computing hardware, for example, one or more processors or computers, to implement the hardware components and perform the methods as described above may be written as computer programs, code segments, instructions or any combination thereof, for individually or collectively instructing or configuring the one or more processors or computers to operate as a machine or special-purpose computer to perform the operations that are performed by the hardware components and the methods as described above. In one example, the instructions or software include machine code that is directly executed by the one or more processors or computers, such as machine code produced by a compiler. In another example, the instructions or software includes higher-level code that is executed by the one or more processors or computer using an interpreter. The instructions or software may be written using any programming language based on the block diagrams and the flow charts illustrated in the drawings and the corresponding descriptions herein, which disclose algorithms for performing the operations that are performed by the hardware components and the methods as described above.

The instructions or software to control computing hardware, for example, one or more processors or computers, to implement the hardware components and perform the methods as described above, and any associated data, data files, and data structures, may be recorded, stored, or fixed in or on one or more non-transitory computer-readable storage media. Examples of a non-transitory computer-readable storage medium include read-only memory (ROM), random-access programmable read only memory (PROM), electrically erasable programmable read-only memory (EEPROM), random-access memory (RAM), dynamic random access memory (DRAM), static random access memory (SRAM), flash memory, non-volatile memory, CD-ROMs, CD-Rs, CD+Rs, CD-RWs, CD+RWs, DVD-ROMs, DVD-Rs, DVD+Rs, DVD-RWs, DVD+RWs, DVD-RAMs, BD-ROMs, BD-Rs, BD-R LTHs, BD-REs, blue-ray or optical disk storage, hard disk drive (HDD), solid state drive (SSD), flash memory, a card type memory such as a multimedia card or a micro card (for example, secure digital (SD) or extreme digital (XD)), magnetic tapes, floppy disks, magneto-optical data storage devices, optical data storage devices, hard disks, solid-state disks, and any other device that is configured to store the instructions or software and any associated data, data files, and data structures in a non-transitory manner and provide the instructions or software and any associated data, data files, and data structures to one or more processors or computers so that the one or more processors or computers can execute the instructions. In one example, the instructions or software and any associated data, data files, and data structures are distributed over network-coupled computer systems so that the instructions and software and any associated data, data files, and data structures are stored, accessed, and executed in a distributed fashion by the one or more processors or computers.

While this disclosure includes specific examples, it will be apparent after an understanding of the disclosure of this application that various changes in form and details may be made in these examples without departing from the spirit and scope of the claims and their equivalents. The examples described herein are to be considered in a descriptive sense only, and not for purposes of limitation. Descriptions of features or aspects in each example are to be considered as being applicable to similar features or aspects in other examples. Suitable results may be achieved if the described techniques are performed in a different order, and/or if components in a described system, architecture, device, or circuit are combined in a different manner, and/or replaced or supplemented by other components or their equivalents.

Therefore, in addition to the above disclosure, the scope of the disclosure may also be defined by the claims and their equivalents, and all variations within the scope of the claims and their equivalents are to be construed as being included in the disclosure.

What is claimed is:

1. An electronic device for defect detection, comprising:
a sensing assembly comprising a plurality of operation elements and a controller; and
one or more processors,
wherein the controller is configured to:
for each of predetermined excitation patterns, activate at least one operation element using at least one control signal to propagate at least one acoustic wave toward a target object, wherein the at least one acoustic wave has at least one frequency based on the at least one operation element; and
acquire a plurality of response signals corresponding to reflected waves sensed by the sensing assembly, the reflected waves being reflections of the at least one acoustic wave reflected from the target object,
wherein the one or more processors are configured to:
analyze the plurality of response signals using an artificial intelligence (AI) model, wherein the AI model is trained to detect defects in the target object based on inputs comprising the response signals respectively corresponding to the excitation patterns.

2. The electronic device of claim 1, wherein each operation element of the plurality of operation elements comprises a film, and wherein the films are reshaped to have distinct thicknesses.

3. The electronic device of claim 2, wherein a resonant frequency of a first operation element of the plurality of operation element is based on a thickness of the film in the first operation element.

4. The electronic device of claim 3, wherein an acoustic wave generated by the first operation element includes at least one of a frequency modulated or an amplitude modulated derived from the resonant frequency.

5. The electronic device of claim 1, further comprising a through-silicon-via (TSV) interposer electrically coupling the controller to the plurality of operation elements.

6. The electronic device of claim 1, wherein the controller includes a plurality of sub-controllers, and
the plurality of operation elements and the plurality of sub-controllers are interconnected via a plurality of through-silicon-via (TSV) interposers.

7. The electronic device of claim 1, wherein the at least one control signal comprises a voltage signal applied to the at least one operation element.

8. The electronic device of claim 2, wherein the plurality of response signals comprise a plurality of voltage signals representing a degree of bending of the films caused by the reflected waves.

9. The electronic device of claim 1, wherein a first excitation pattern of the excitation patterns defines activation of a subset of the plurality of operation elements and deactivation of remaining operation elements of the plurality of operation elements.

10. The electronic device of claim 9, wherein a first operation element of the plurality of operation elements is activated in at least one excitation pattern among the excitation patterns.

11. The electronic device of claim 1, wherein when the at least one acoustic wave is propagated on a first surface of the sensing assembly, and when the reflected waves are reflected on a second surface of the target object, an area of the first surface is larger than that of the second surface.

12. The electronic device of claim 1, wherein the AI model is trained using:
first learning data comprising response signals from first objects as non-defective objects; and
second learning data comprising response signals from second objects as defective objects,
to distinguish the first objects and the second objects.

13. The electronic device of claim 12, wherein the first learning data comprises pairs of the excitation patterns and response signals from the first objects, and
the second learning data comprises pairs of the excitation patterns and response signals from the second objects.

14. The electronic device of claim 1, wherein each of the plurality of operation elements comprises a micro-electro-mechanical system (MEMS), and
the target object comprises a semiconductor wafer.

15. A defect detection method for an electronic device comprising one or more processors and a sensing assembly with a plurality of operation elements and a controller, the method comprising:
activating, via the controller, for each of predetermined excitation patterns, at least one operation element using at least one control signal to propagate at least one acoustic wave toward a target object; wherein the at least one acoustic wave has at least one frequency based on the at least one operation element;
acquiring, via the controller, a plurality of response signals corresponding to reflected waves sensed by the sensing assembly, the reflected waves being reflections of the at least one acoustic wave reflected from the target object; and
determining, via the one or more processors, a defect status of the target object by analyzing an artificial intelligence (AI) model trained to correlate the response signals with defects.

16. The method of claim 15, further comprising:
performing the defect detection method after each step of a multi-step manufacturing process for the target object; and
generating an alert identifying a specific manufacturing step when defects reaching or exceeding a predetermined threshold are detected in the target object after said step.

17. A non-transitory computer-readable recording medium storing instructions that, when executed by a processor, cause the processor to perform the method of claim 15.
